(19) United States
(12) Patent Application Publication
(10) Pub. No.: US 2024/0419847 A1
(43) Pub. Date: Dec. 19, 2024

(54) Method of Manufacturing Analysis with Ontologies and Semantic Analysis

(71) Applicant: The Boeing Company, Arlington, VA (US)

(72) Inventor: John Makoto Shinozaki, Kenmore, WA (US)

(21) Appl. No.: 18/641,819

(22) Filed: Apr. 22, 2024

Related U.S. Application Data
(60) Provisional application No. 63/508,188, filed on Jun. 14, 2023.

(51) Int. Cl. G06F 30/10

(52) U.S. Cl. CPC G06F 30/10

(57) ABSTRACT

Manufacturing analysis is provided. The method comprises identifying a feature of a product model defined by geometric, physical, and systems elements with semantic labels, names or title descriptions. Machine readable semantic links are created that connect the feature to elements in an enterprise knowledge library according to a machine readable ontological knowledge model. A producibility risk or opportunity for the product model is identified according to semantic relationships of the elements in the enterprise knowledge library linked to the feature. A user is alerted of the producibility risk or opportunity, and a note is added to a manufacturing design specification for the product model. The note provides a number of solutions for the producibility risk or opportunity, wherein the solutions are identified in the enterprise knowledge library according to the semantic relationships.

### CROSS-REFERENCE TO RELATED APPLICATION

This application claims the benefit of U.S. Provisional Patent Application Ser. No. 63/508, 188, filed Jun. 14, 2023, and entitled “Method of Manufacturing Anaysis with Ontologies and Semantic Analysis,” which is incorporated herein by reference in its entirety.

### BACKGROUND INFORMATION

### Technical Field

The present disclosure relates generally to manufacturing, and more specifically to computer-aided modeling systems for manufacturing.

### Background

Manufacturing has a primary requirement set which comes from the product to be manufactured. Requirements may be derived from three-dimensional (3D) specifications used in computer-aided modeling. Computer-aided modeling or computer-aided design (CAD) creates virtual models of objects or systems, which allows engineers and designers to visualize and simulate structures or processes. Manufacturing can get requirements from other system domains such as facility requirements/constraints, equipment and tooling constraints, or Human Factor requests.

Such manufacturing requirements may have implications for product design. However, manufacturing requirements derived from 3D specifications typically only flow down to manufacturing operations.

Traditionally, feedback from manufacturing can be late and only done through engineering and stakeholder design review meetings, siloed spreadsheet or document design review checklists, or Manufacturing (or other domains like Human Factors) change requests or risk item reports. All methods require humans to identify the risk or opportunity by reviewing the specification themselves and either using their expertise knowledge or reference material as disconnected data.

### SUMMARY

An illustrative embodiment provides a computer-implemented method of manufacturing analysis. The method comprises identifying a feature of a product model defined by geometric, physical, and systems elements with semantic labels, names or title descriptions. Machine readable semantic links are created that connect the feature to elements in an enterprise knowledge library according to a machine readable ontological knowledge model. A producibility risk or opportunity for the product model is identified according to semantic relationships of the elements in the enterprise knowledge library linked to the feature. A user is alerted of the producibility risk or opportunity, and a note is added to a manufacturing design specification for the product model. The note provides a number of solutions for the producibility risk or opportunity, wherein the solutions are identified in the enterprise knowledge library according to the semantic relationships.

Another illustrative embodiment provides a system for manufacturing analysis. The system comprises a storage device that stores program instructions and one or more processors operably connected to the storage device and configured to execute the program instructions to cause the system to: identify a feature of a product model defined by geometric, physical, and systems elements with semantic labels, names or title descriptions; create machine readable semantic links that connect the feature to elements in an enterprise knowledge library according to a machine readable ontological knowledge model; identify a producibility risk or opportunity for the product model according to semantic relationships of the elements in the enterprise knowledge library linked to the feature; alert a user of the producibility risk or opportunity; and add a note to a manufacturing design specification for the product model, wherein the note provides a number of solutions for the producibility risk or opportunity, wherein the solutions are identified in the enterprise knowledge library according to the semantic relationships.

Another illustrative embodiment provides a computer program product for manufacturing analysis. The compute program product comprises a computer-readable storage medium having program instructions embodied thereon to perform the operations of: identifying a feature of a product model defined by geometric, physical, and systems elements with semantic labels, names or title descriptions; creating machine readable semantic links that connect the feature to elements in an enterprise knowledge library according to a machine readable ontological knowledge model; identifying a producibility risk or opportunity for the product model according to semantic relationships of the elements in the enterprise knowledge library linked to the feature; alerting a user of the producibility risk or opportunity; and adding a note to a manufacturing design specification for the product model, wherein the note provides a number of solutions for the producibility risk or opportunity, wherein the solutions are identified in the enterprise knowledge library according to the semantic relationships.

The features and functions can be achieved independently in various embodiments of the present disclosure or may be combined in yet other embodiments in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is a pictorial representation of a network of data processing systems in which illustrative embodiments can be implemented;

FIG. 2 is an illustration of a block diagram of a manufacturing analysis system in accordance with an illustrative embodiment;

FIG. 3 illustrates the relationship between a product model and manufacturing process steps in accordance with an illustrative embodiment;

FIG. 4 depicts a production system model in accordance with an illustrative embodiment;

FIG. 5 depicts a semantic knowledge graph in accordance with an illustrative embodiment;

FIG. 6 depicts a knowledge table in accordance with an illustrative embodiment;

FIG. 7 depicts an alert and resolution table superimposed on the production system model in accordance with an illustrative embodiment;

FIG. 8 depicts an alert and resolution graph superimposed on the production system model in accordance with an illustrative embodiment;

FIG. 9 shows the application of data graphs to product development specifications in accordance with an illustrative embodiment;

FIG. 10 depicts a flowchart of a process for manufacturing analysis in accordance with an illustrative embodiment; and

FIG. 11 is an illustration of a block diagram of a data processing system in accordance with an illustrative embodiment.

### DETAILED DESCRIPTION

The illustrative embodiments recognize and take into account that manufacturing requirements are often derived from 3D specifications used in computer-aided modeling, and such manufacturing requirements may have implications for product design.

The illustrative embodiments also recognize and take into account that manufacturing requirements derived from 3D modeling specifications and annotations typically only flow down to manufacturing operations.

The illustrative embodiments provide a method to flow requirements from downstream domains such as manufacturing, human factors, equipment engineering, and tooling engineering back to the product design stage. This flow back process allows design engineers to take remedial action to the product standards or product design. The illustrative embodiments also integrate design and product data to identify production risks and opportunities and provide solutions.

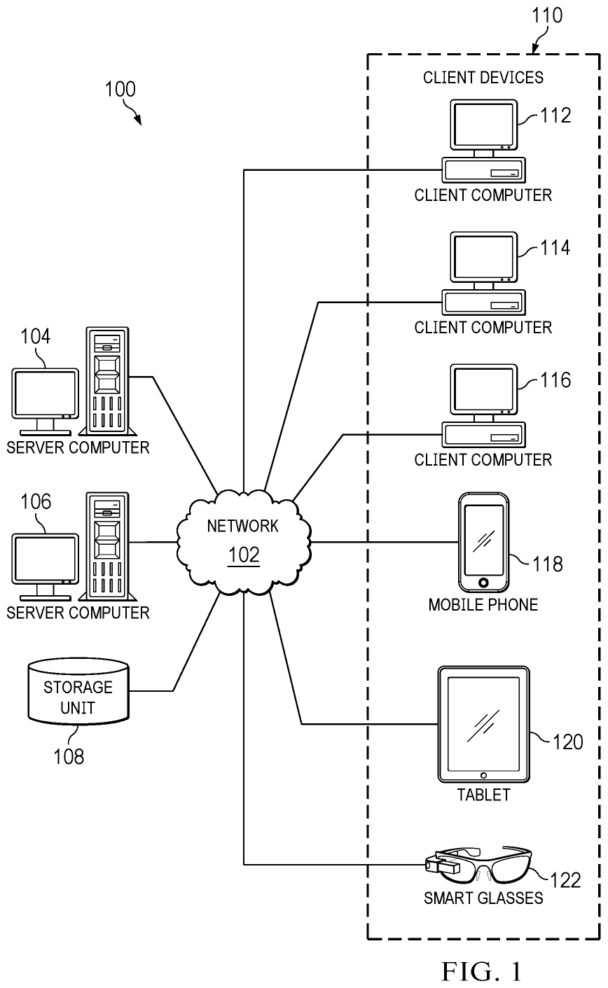

With reference to FIG. 1, a pictorial representation of a network of data processing systems is depicted in which illustrative embodiments may be implemented. Network data processing system 100 is a network of computers in which the illustrative embodiments may be implemented. Network data processing system 100 contains network 102, which is the medium used to provide communications links between various devices and computers connected together within network data processing system 100. Network 102 might include connections, such as wire, wireless communication links, or fiber optic cables.

In the depicted example, server computer 104 and server computer 106 connect to network 102 along with storage unit 108. In addition, client devices 110 connect to network 102. In the depicted example, server computer 104 provides information, such as boot files, operating system images, and applications to client devices 110. Client devices 110 can be, for example, computers, workstations, or network computers. As depicted, client devices 110 include client computers 112, 114, and 116. Client devices 110 can also include other types of client devices such as mobile phone 118, tablet computer 120, and smart glasses 122.

In this illustrative example, server computer 104, server computer 106, storage unit 108, and client devices 110 are network devices that connect to network 102 in which network 102 is the communications media for these network devices. Some or all of client devices 110 may form an Internet of things (IoT) in which these physical devices can connect to network 102 and exchange information with each other over network 102.

Client devices 110 are clients to server computer 104 in this example. Network data processing system 100 may include additional server computers, client computers, and other devices not shown. Client devices 110 connect to network 102 utilizing at least one of wired, optical fiber, or wireless connections.

Program code located in network data processing system 100 can be stored on a computer-recordable storage medium and downloaded to a data processing system or other device for use. For example, the program code can be stored on a computer-recordable storage medium on server computer 104 and downloaded to client devices 110 over network 102 for use on client devices 110.

In the depicted example, network data processing system 100 is the Internet with network 102 representing a worldwide collection of networks and gateways that use the Transmission Control

Protocol/Internet Protocol (TCP/IP) suite of protocols to communicate with one another. At the heart of the Internet is a backbone of high-speed data communication lines between major nodes or host computers consisting of thousands of commercial, governmental, educational, and other computer systems that route data and messages. Of course, network data processing system 100 also may be implemented using a number of different types of networks. For example, network 102 can be comprised of at least one of the Internet, an intranet, a local area network (LAN), a metropolitan area network (MAN), or a wide area network (WAN). FIG. 1 is intended as an example, and not as an architectural limitation for the different illustrative embodiments.

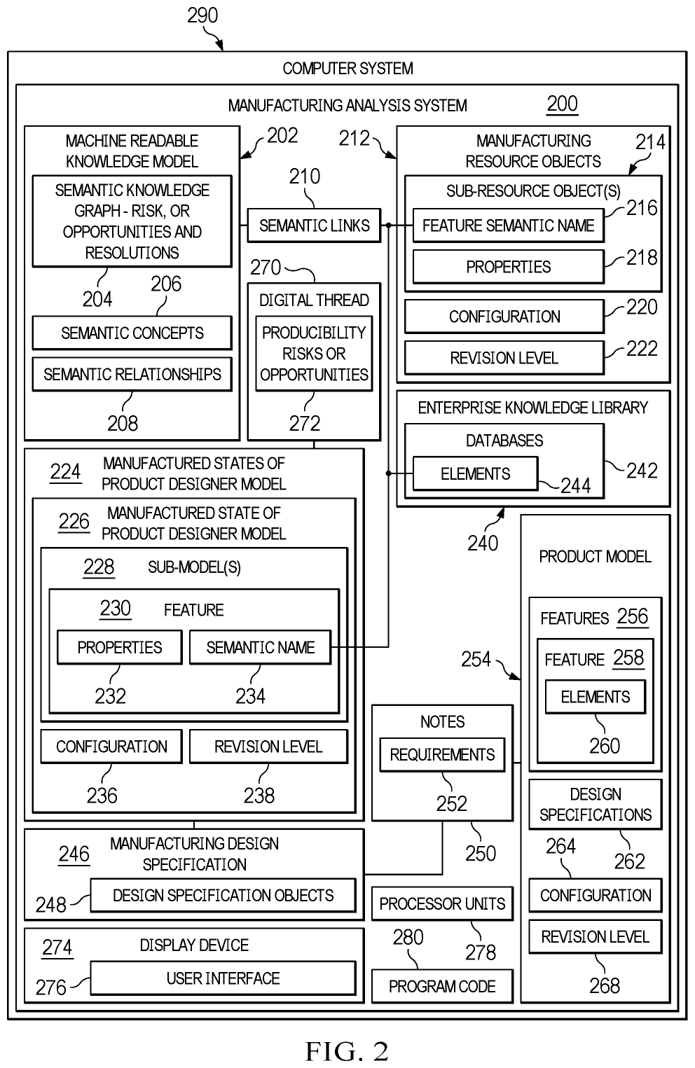

With reference now to FIG. 2, an illustration a block diagram of a manufacturing analysis system is depicted in accordance with an illustrative embodiment. In this illustrative example, manufacturing analysis system 200 includes components that can be implemented in hardware such as the hardware shown in network data processing system 100 in FIG. 1.

Manufacturing analysis system 200 comprises a machine readable knowledge model 202 that provides an ontological framework for establishing semantic connections between an article of manufacture and cumulative, dispersed enterprise knowledge related to production methods and available manufacturing resources. Machine readable knowledge model 202 might be presented as a semantic knowledge graph 204, which can be displayed by display device 274. Machine readable knowledge model 202 comprise a number of semantic concepts 206 related to an article of manufacture and methods and resources for manufacturing it and models semantic relationships 208 between those semantic concepts.

Manufacturing analysis system 200 also comprises a manufacturing resource object 212 which might represent a production system model related to manufacturing resources used to produce an article of manufacture. Manufacturing resource object 212 might comprise a number of sub-resource objects 214. Each sub-resource object 214 comprises a number of properties 218 and a feature semantic name 216. Manufacturing resource object 212 might represent a specific configuration 220 and revision level 222 for the article of manufacture in question. As the configuration 220 and revision level 222 change so might the sub-resource object(s) 214 comprising the manufacturing resource object 212.

Manufacturing analysis system 200 comprises an enterprise knowledge library 240 that includes a number of databases 242 relevant to designing and producing the article of manufacture. Enterprise knowledge library 240 brings together cumulative and dispersed institutional knowledge related to manufacturing methods, resources, articles of manufacture, etc., as well as risks and opportunities for improvement related to these categories based on past experience. Enterprise knowledge library 240 can be continually updated.

Enterprise knowledge library 240 pulls together several databases 242 comprising elements 244. For example, databases 242 might include a database for manufacturing processes and process standards relevant to a feature, part, object or assembly of objects. Databases 242 might also include a database of design guidance, manuals, recommendations, checklists, processes, and practices. Another example is a database of manufacturing assets relevant to manufacturing processes for an article of manufacture. Another example is a database of previously-identified non-conformances, defects, failure modes effect analysis, or risks relevant to manufacturing processes for the article of manufacture and means of resolution or improvement of the processes. Databases 242 might also include a database of formally modeled, machine-readable ontologies unique to a company's intellectual property, research, interests and business, and industry standards.

The article of manufacture in question is represented by product model 254, which comprises a number of defining features 256. Each feature 258 comprises a number functional or physical, structural, geometric elements 260. Features 256 are determined by design specifications 262 and a configuration 236 of the article of manufacture, which may change according to the revision level 268 of the design of the article.

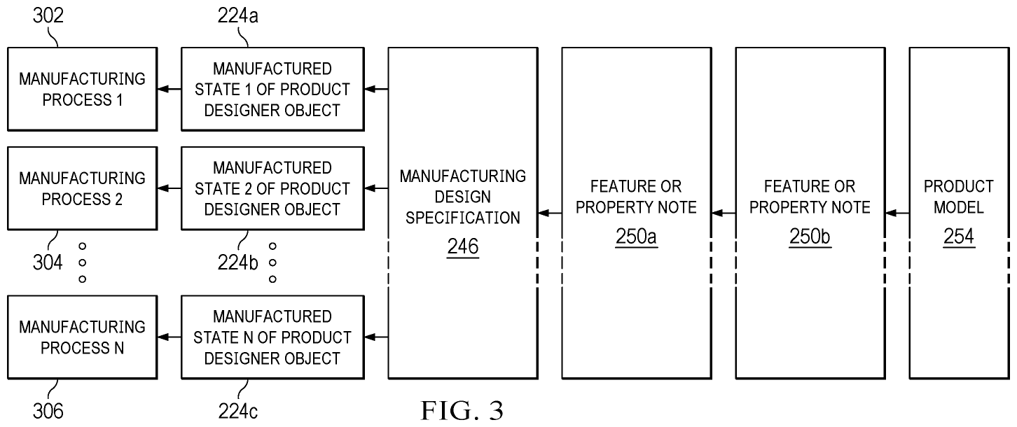

Product model 254 is converted to a manufacturing design specification 246 comprising a number of design specification objects 248 such as would be used in computer aided design (CAD) and requirements modeling. The manufacturing design specification 246 can be used to define a number of manufactured states 224 of product model 254 (see FIG. 3). Each manufactured state 226 represents a different step in the manufacturing process for the product model 254, which is subject to change according to a configuration 236 and revision level 238, which correspond to the configuration 264 and revision level 268 of the product model 254.

A manufactured state 226 relates to a number of sub-objects 228 that might be added, removed, modified, etc., regarding a feature 230 corresponding to feature 258 of the product model 254. Feature 230 includes properties 232 and a semantic name 234.

Machine readable knowledge model 202 provides an ontological framework for creating machine readable semantic links 210 that connect and interrelate the manufacturing resource object 212, enterprise knowledge library 240, and product model 254 (via manufactured states 224 and manufacturing design specification 246). The semantic links 210 add context to the model represented by manufacturing design specification 246 based on classifications in the enterprise knowledge library 240.

Through this context, semantic links 210 facilitate the identification of potential producibility risks or opportunities for improvement to a production process/model based on past experience and institutional know how recorded in the enterprise knowledge library 240. The producibility risks or opportunities can be brought to the attention of a user via user interface 276 in display device 274.

The identification of these producibility risks or opportunities leads to the creation of notes 250 comprising requirements 252 that can be added to the manufacturing design specification 246 as new design specification objects 248. Note 250 is from Manufacturing Engineering to make the product model 254 more producible. This note 250 can constrain and cause changes to the features 256, design specifications 262, configuration 264 and consequently revision level 268. Notes 250 from Manufacturing/Production Engineering can go either way. It can flow requirements to the product model 254 and then into the manufactured states 224 of product model.

The program code 280 and processor units 278 can use generative artificial intelligence (AI) to make suggestions which turn into design specification objects 248. A user might read the suggestion from the generative AI code, and then write a design specification object/suggestion to the product model 254. Alternatively, a generative AI script can provide a design specification object 248 from the databases 242.

As the information and generative AI code becomes more precise and accurate the production system and articles of manufacture (e.g., aircraft, automobiles, etc.) can be modeled and designed automatically through semantic search via semantic links. AI algorithms can be trained to provide increasingly better suggestions, allowing design and modeling to move from focus on singular elements to larger more complex solutions models.

Manufacturing analysis system 200 generates a digital thread 270 that collects the producibility risks or opportunities 272 and measured criteria relevant to the producibility risks or opportunities and links them to a final product for quality assurance.

The display device 274 can include at least one of a light emitting diode (LED) display, a liquid crystal display (LCD), an organic light emitting diode (OLED) display, a computer monitor, a projector, a flat panel display, a heads-up display (HUD), a head-mounted display (HMD), or some other suitable device that can output information for the visual presentation of information.

Manufacturing analysis system 200 can be implemented in software, hardware, firmware, or a combination thereof. When software is used, the operations performed by manufacturing analysis system 200 can be implemented in program code configured to run on hardware, such as a processor unit. When firmware is used, the operations performed by manufacturing analysis system 200 can be implemented in program code and data and stored in persistent memory to run on a processor unit. When hardware is employed, the hardware can include circuits that operate to perform the operations in manufacturing analysis system 200.

In the illustrative examples, the hardware can take a form selected from at least one of a circuit system, an integrated circuit, an application specific integrated circuit (ASIC), a programmable logic device, or some other suitable type of hardware configured to perform a number of operations. With a programmable logic device, the device can be configured to perform the number of operations. The device can be reconfigured at a later time or can be permanently configured to perform the number of operations. Programmable logic devices include, for example, a programmable logic array, a programmable array logic, a field programmable logic array, a field programmable gate array, and other suitable hardware devices. Additionally, the processes can be implemented in organic components integrated with inorganic components and can be comprised entirely of organic components excluding a human being. For example, the processes can be implemented as circuits in organic semiconductors.

Computer system 290 is a physical hardware system and includes one or more data processing systems. When more than one data processing system is present in computer system 290, those data processing systems are in communication with each other using a communications medium. The communications medium can be a network. The data processing systems can be selected from at least one of a computer, a server computer, a tablet computer, or some other suitable data processing system.

As depicted, computer system 290 includes a number of processor units 278 that are capable of executing program code 280 implementing processes in the illustrative examples. As used herein a processor unit in the number of processor units 278 is a hardware device and is comprised of hardware circuits such as those on an integrated circuit that respond and process instructions and program code that operate a computer. When a number of processor units 278 execute program code 280 for a process, the number of processor units 278 is one or more processor units that can be on the same computer or on different computers. In other words, the process can be distributed between processor units on the same or different computers in a computer system. Further, the number of processor units 278 can be of the same type or different type of processor units. For example, a number of processor units can be selected from at least one of a single core processor, a dual-core processor, a multi-processor core, a general-purpose central processing unit (CPU), a graphics processing unit (GPU), a digital signal processor (DSP), or some other type of processor unit.

The Manufacturing Analysis System 200 helps to digitally thread and make more visible and useful the manufacturing quality challenges detected, resolved, and reported in siloed databases. The following examples help illustrate the application of manufacturing analysis system 200.

The first example is the application of a non-destructive inspection (NDI) ultrasonic, water coupling pulse echo system to a composite panel for defects. A feature on that composite panel may become curved, wavey, or bumpy during manufacturing. This knowledge is captured in the Machine Readable Knowledge Model 202 and Enterprise Knowledge Library 240 and not specified or known within the Product Model 254 and Manufactured States of Product Model 224. The inspectability risk here is that the end of the probe can trip over bumps if on the near-side surface or lose the signal as it echoes off the farside surface that is too wavey.

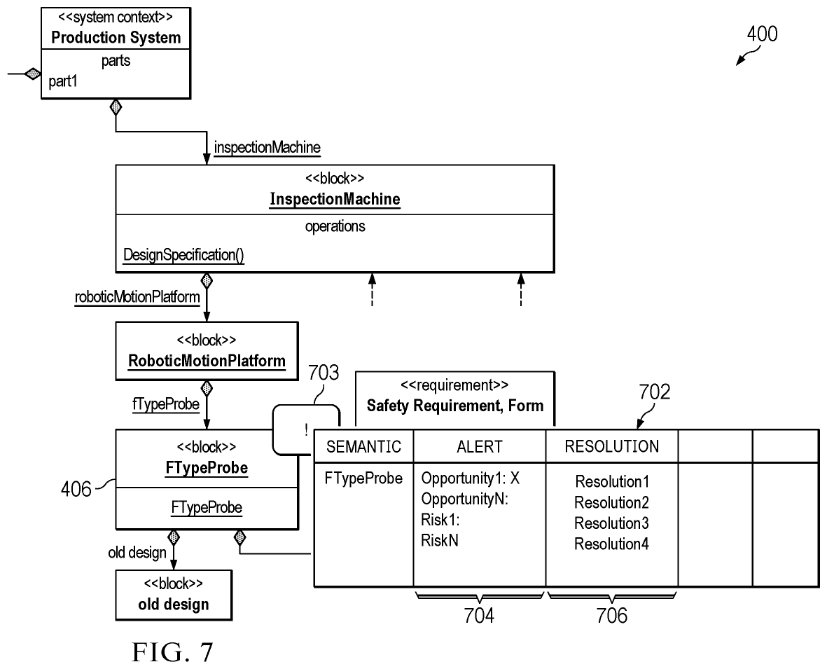

The semantic knowledge graph 204 can associate this issue with the cause of the bumps and waves, which can be a Manufacturing Resource Object 212. The Manufacturing Resource Object 212 semantics will highlight in multiples ways (e.g., semantic phrase or alert 703 in FIG. 7) and one can click on the semantic phrase or alert 703 to see the Resolution Table 702 which shows potential producibility risks or opportunities 704 (see FIG. 7). A risk 704 can show that the NDI system cannot scan over certain types of waves and bumps and will recommend a resolution 706. One can realize the suggested resolution by turning it into a Note 250 from Resolution 706. The Note 250 can be a natural language text description with images, process instructions, a standard structured text specification, programming code, or a parametric value, array or equation. The Note 250 can be referenced as an instance within the specification of the design specification 248 of Manufacturing Design Specification 246 or the design specification 262 of Product Model 254.

Another similar example is the application of a non-destructive inspection (NDI) ultrasonic, water coupling, pulse echo inspection system, wherein the backside surface of a composite panel is wet. In this situation, the water can interfere with the return of the ultrasonic signals, leading to a corrupted or distorted return signals. This corrupted signal data can affect the accuracy and reliability of defect detection in the composite panel. Again, this knowledge is captured in the Machine Readable Knowledge Model 202 and Enterprise Knowledge Library 240 and not necessarily specified within the Manufactured States of Product Model 224. The inspectability risk here is that during inspection scanning, the backside surface needs to be dry. The semantic knowledge graph 204 can associate this issue by suggesting a Resolution 706, which can be a Note 250 for the Manufacturing Design Specification 246, which will specify requirements for Manufactured Stated of Product Model 224 to be dry on back-side surface during NDI scanning. Manufacturing Operations can define requirements for a Manufacturing Resource Object 212 to keep the backside surface dry. Therefore, the Manufacturing Resource Object 212 can be a water shield or tools to blow dry the backside surface.

The above examples illustrate the ability of the illustrative embodiments to integrate information from historically isolated information sources into actionable information that is unaccounted for in product models and would otherwise be omitted from manufacturing design specifications and manufacturing procedures for a product.

FIG. 3 illustrates the relationship between a product model and manufacturing process steps in accordance with an illustrative embodiment. Product model 254 is converted to a manufacturing design specification 246 (i.e., CAD model). A number of manufactured states 224a-224c are derived from the manufacturing design specifications 246, corresponding to respective manufacturing processes 302-306 for different production stages of the article of manufacture represented by the product model 254.

A number of feature or property notes 250a-250b can be added to constrain the manufacturing design specifications 246 according to the identification of producibility risks or opportunities identified from the enterprise knowledge library. There might be any number of feature or property notes at different levels of granularity of the product model.

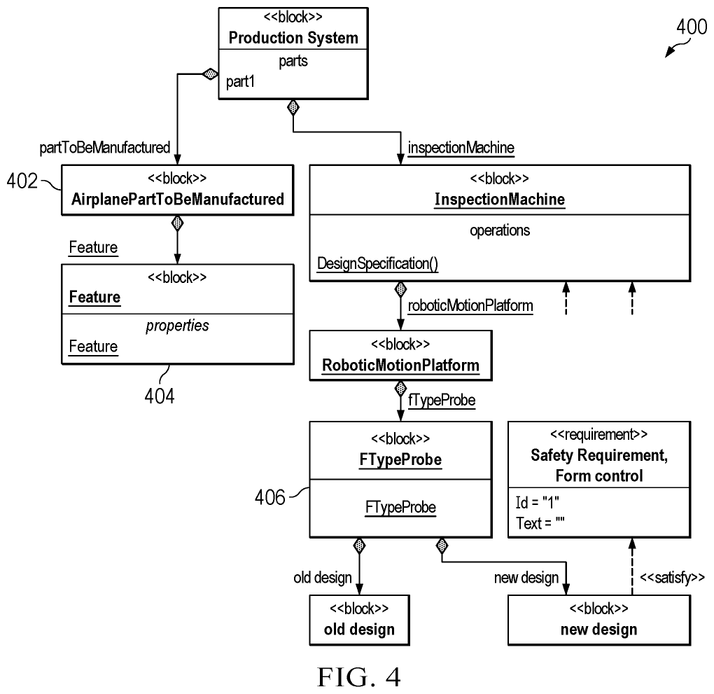

FIG. 4 depicts a production system model in accordance with an illustrative embodiment. Production system model 400 might be represented by manufactured states 224 of product models and manufacturing resource objects 212 in FIG. 2.

The example production system model 400 shown in FIG. 4 is present using systems modeling language (SysML). In the present example, production system model 400 relates to an airplane part 402 to be manufactured. A feature of this part has been identified as a feature component 404. This feature component 404 needs to be integrated with an F-type probe 406. These feature integration risks may not be known in advance. However, preexisting information in manufacturing databases can flag this issue through knowledge graphs.

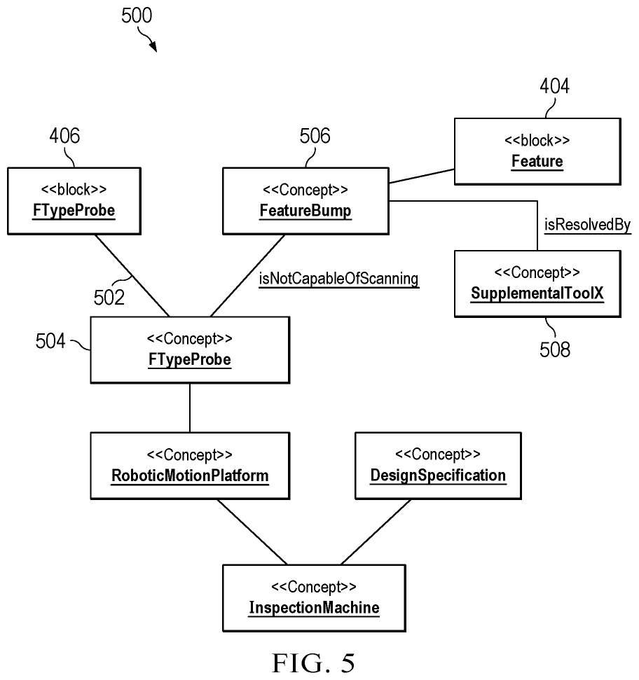

FIG. 5 depicts a semantic knowledge graph in accordance with an illustrative embodiment. Knowledge graph 500 might be an example of semantic knowledge graph 202 in FIG. 2.

Semantic knowledge graph 500 is represented as a graph with nodes and edges which can be displayed to a user in a graphical user interface such as user interface 276 in FIG. 2.

FIG. 5 illustrates an example of how a user can navigate from production system model. Production system model 400 has a «Block» 406 in SysML language with semantic name FTypeProbe. (In FIG. 2, this block would constitute a feature semantic name 216.) Semantic link 502 links «Block» 406 to «Concept» FTypeProbe 504 in the semantic knowledge graph 500.

The semantics from «Concept» FTypeProbe 504 to isNotCapableOfScanning for semantic concept «Concept» Feature 506. «Concept» Feature 506 in turn is semantically linked to semantic concept «Concept» SupplementalToolX 508. If that semantic concept is linked to other semantics in the model, the user can navigate into the enterprise knowledge library and databases, which might contain risk elements and resolution elements (example of elements 244 in FIG. 2). They can have the semantics SupplementalToolX.

The illustrative embodiments can analyze semantic features that are known to have issues that have been discovered in the past through testing on characteristics that do show up in the model, and therefore need to be controlled through notes. While CAD does specify parametric features like points, lines, planes and solids, the semantics on those features can provide hints to manufacturing quality characteristics that are also problematic that can be resolved through additional notes (not necessarily direct, parametric design changes).

For example, manufacturing quality of co-cured vents leads to resin ridges around caul plates, which is not explicitly known or specified in CAD GD&T (Geometric Dimensioning and Tolerancing). This effect is known through testing and controlled through design guidance, notes, which can eventually lead to Caul Plate geometric design optimization to reduce thickness along edges that lead to resin build up. Alternatively, it can specify a sanding operation after debag, to get rid of all the bumps before NDI, so that the probes don't get snagged. This knowledge is buried in R&D documents siloed on servers. The illustrative embodiments find a way to link those pieces of information to relevant terms a product modeler might put on a new product model.

As another example, manufacturing quality of a composite wing panel can have the backside surface wet for a variety of reasons which is not favorable when NDI pulse echo scanning methods are used on the front side. For example, a wash situation prior to NDI can leave the back side wet if not dried in advance. Or the water used as a couplant during NDI gets splashed and dripping down the backside surface. The semantic knowledge graph can pick this up and warn the production system designer to design features to block water from getting to the back side or to wipe and dry the back side with a variety of tools and methods prior to NDI scan.

In some cases, the enterprise knowledge library might have billions of elements related to the same single semantic phrase. Therefore, model context and specific semantics and definition/meaning can be used to narrow down relevant elements. Advance scripts can be written to filter the relationships.

There are many variants to navigating the semantics links to see risk or opportunity and the resolution that comes along with it. A user can manually point, click, and look for meaningful, relevant information. Scripts can filter a portion of relation. Program code might automatically look at model context and the semantic knowledge, enterprise knowledge library, databases, of all models, and find relevant suggestions for the user on risk and resolution elements. This process might be performed by a background manufacturing analysis engine that is continuously flagging or suggesting ideas in the model.

The program code can be smart enough to see that a manufacturing resource object 212 (e.g., FTypeProbe) cannot scan a manufactured state 226 of a product model 254 (e.g., Feature), and search the enterprise knowledge library 240 and databases 242 to find a SupplementalToolX and design specification object elements.

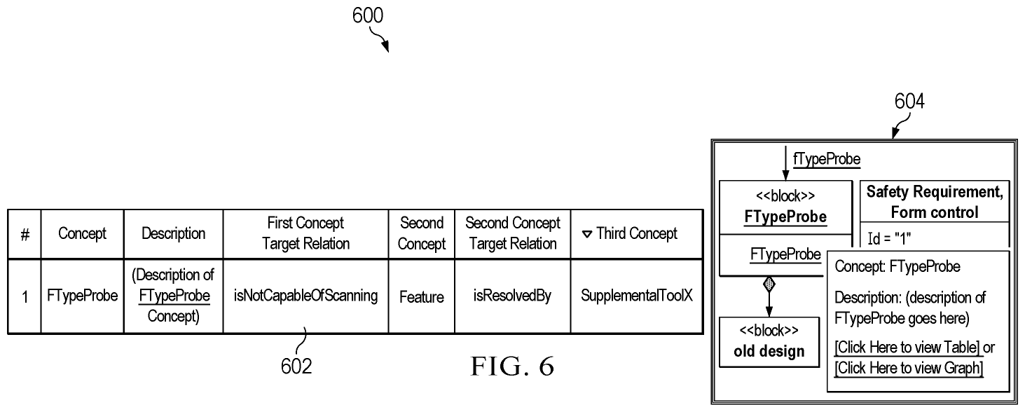

FIG. 6 depicts a knowledge table in accordance with an illustrative embodiment. Knowledge table 600 is an alternate presentation of machine readable knowledge model 202 in FIG. 2.

Also shown is a description window 604, which can be called up by the user by clicking on or hovering over an active semantic link related to the description of a concept/phrase in knowledge table 600. In the example shown, the semantic link 602 (represented by underlining) and description window 604 are related to the F-type probe. It should be noted that similar active semantic links pop up description windows can be employed with semantic knowledge graph 500.

A glossary profile allows a user to link across a model (which can be any type of model, such as a logical block model or CAD model with semantics/phrases) to a semantic knowledge graph such as semantic knowledge graph 500.

In addition to showing the definition of the concept/phrase in question, description window 604 can also relate producibility risks or opportunities to the term.

FIG. 7 depicts an alert and resolution table superimposed on the production system model in accordance with an illustrative embodiment. This example illustrates the use of a semantic link in the production system model 400 related to the F-type probe 406. By clicking or hovering over the link, alert 703 and resolution table 702 appears, which includes a number of potential risks and opportunities 704 related to the F-type probe 406. Alternatively, alert 703 may already be displayed in the model across different concepts/phrase on the object/model and hovering over the alert to call up the resolution table 702. Also shown in description alert and resolution table 702 are corresponding resolution processes 706 to address each of the risks or opportunities 704.

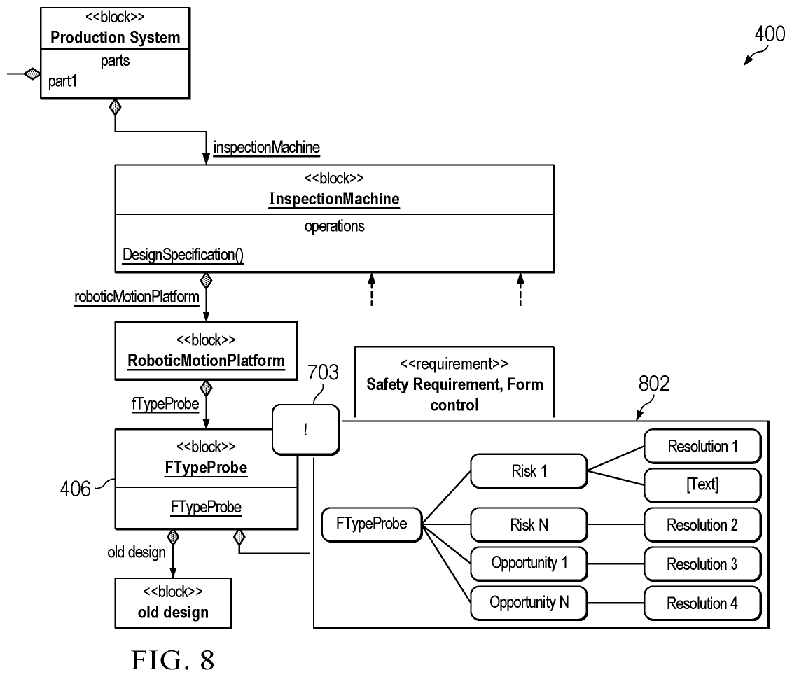

FIG. 8 depicts an alert and resolution graph superimposed on the production system model in accordance with an illustrative embodiment. The example shown in FIG. 8 is substantively similar to that shown in FIG. 7. In this example, activating the semantic link related to the F-type probe 406 in production system model 400 calls up alert 703 and resolution graph 802, which presents the same information as that shown in alert and resolution table 702 in FIG. 7. Similar to FIG. 7, alert 703 may also already be displayed in the model across different concepts/phrase on the object/model and hovering over the alert to call up the resolution table 802. Generative AI might also be activated to present high priority alerts, as well as color code them, depending on the level of sensitivity or criticality of risks that need to be presented.

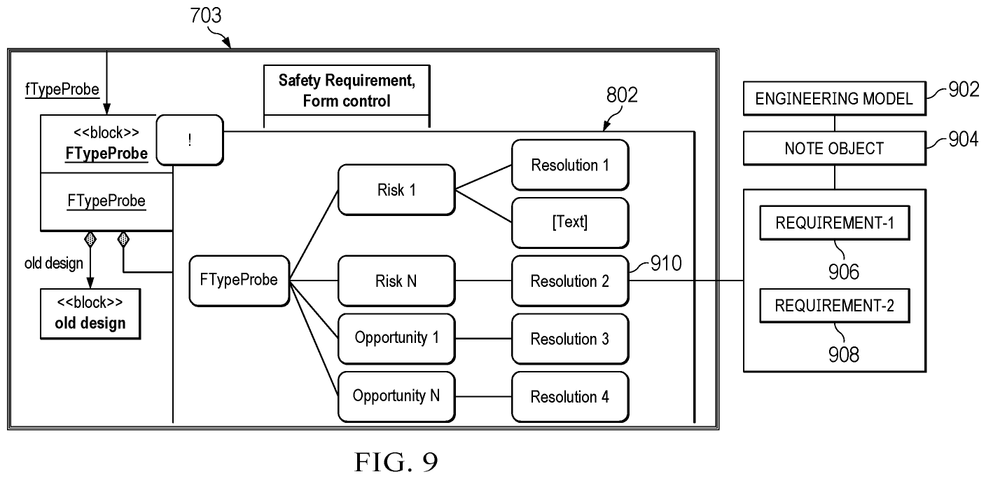

FIG. 9 shows the application of data graphs to product development specifications in accordance with an illustrative embodiment. Once a relevant risk or opportunity is identified for a feature, a note object 904 (note 250) can be created within the product design model 902.

Identifying and reusing risk or issue objects from alert and resolution graph 802 can speed up the development process and improve quality of risk analysis by finding a relevant solution if it already exists in the knowledge base. The user can use resolutions from alert 703 and resolution graph 802 to create design requirement objects 906, 908, which are then imported into the product development engineering model 902 to specify a design solution and retire a risk or capture an opportunity. In this context, the solution is coming from manufacturing to make the product design more producible.

Therefore, the resolution 910 to a risk from alert 703 and resolution graph 802 can become part of the design requirements and can be reused from one development program to another.

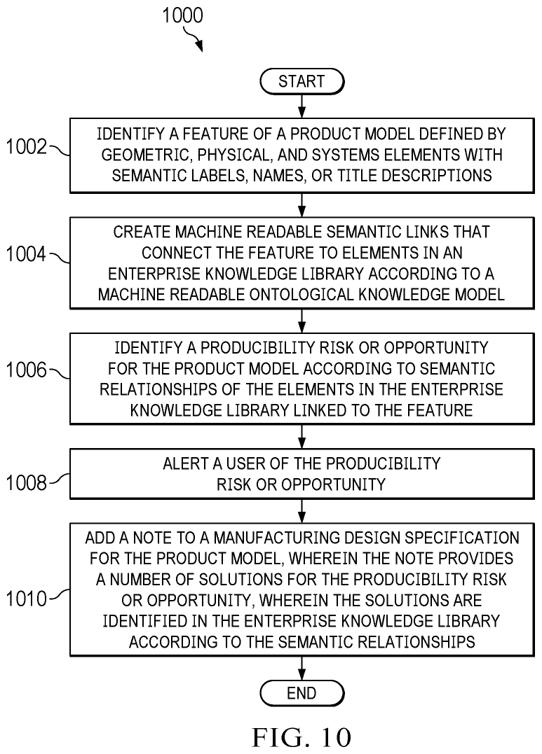

FIG. 10 depicts a flowchart of a process for manufacturing analysis in accordance with an illustrative embodiment. The process in FIG. 10 can be implemented in hardware, software, or both. When implemented in software, the process can take the form of program code that is run by one of more processor units located in one or more hardware devices in one or more computer systems. For example, the process can be implemented in manufacturing analysis system 200 in computer system 290 in FIG. 2.

Process 1000 begins by identifying a feature of a product model defined by geometric, physical, and systems elements with semantic labels, names or title descriptions (operation 1002). The feature of the producer object might comprise an entity within a computer aided design (CAD) environment that defines geometric or functional portion of a part. Examples of features might include Package folder, Collector, System Block, Behavior, Object, Object Property, Object Method, Physical product, Part, 3D Shape specification, Annotation set, Note, points, lines, planes, curves, surfaces, or solid shapes.

The geometric, physical, and systems elements of the feature might include material properties, ply stack thickness, radius of curvature, manufacturing features (e.g., required excess), manufacturing quality; manufacturing tools, machining specifications, painting specifications, inspection specifications, wash and dry processes index tool coordination features, tool coordination, geometric dimensioning and tolerancing, transportation, handling, and logistic features.

Process 1000 creating machine readable semantic links that connect the feature to elements in an enterprise knowledge library according to a machine readable ontological knowledge model (operation 1004). The manufacturing process library might be comprised of a number of databases. These databases might include, for example, a database of manufacturing processes and process standards relevant to a feature, part, object or assembly of objects, a database of design guidance, manuals, recommendations, checklists, processes, and practices, a database of manufacturing assets relevant to manufacturing processes for the object, a database of previously-identified non-conformances, defects, failure modes effect analysis, or risks relevant to manufacturing processes for the object and means of resolution or improvement of the processes, and a database of formally modeled, machine-readable ontologies unique to a company's intellectual property, research, interests and business, and industry standards.

Process 1000 identifying a producibility risk or opportunity for the product model according to semantic relationships of the elements in the enterprise knowledge library linked to the feature (operation 1006). Identifying the producibility risk or opportunity for the product model of might be performed through semantic analysis of the enterprise knowledge library. Identifying the producibility risk or opportunity might be performed via natural language processing (NLP). A digital thread can be used to collect and link the producibility risk or opportunity, and measured criteria relevant to the producibility risk or opportunity, to a final product for quality assurance.

Process 1000 alerts a user of the producibility risk or opportunity (operation 1008).

Process 1000 adds a note to a manufacturing design specification for the product model, wherein the note provides a number of solutions for the producibility risk or opportunity, wherein the solutions are identified in the enterprise knowledge library according to the semantic relationships, thereby integrating information from the enterprise knowledge library into actionable information that is unaccounted for in the product model and would otherwise be omitted the from manufacturing design specification (operation 1010).

The solutions for the producibility risk or opportunity comprise at least one of a change of design specifications of the object or a change of configuration of the object. Examples of design specifications or configurations that might be changed include material properties, ply stack thickness, radius of curvature, manufacturing features (e.g., required excess), manufacturing quality; manufacturing tools, machining specifications, painting specifications, inspection specifications, wash and dry processes index tool coordination features, tool coordination, geometric dimensioning and tolerancing, transportation, handling, and logistic features.

Process 1000 then ends.

The flowchart and block diagrams in the different depicted embodiments illustrate the architecture, functionality, and operation of some possible implementations of apparatuses and methods in an illustrative embodiment. In this regard, each block in the flowcharts or block diagrams can represent at least one of a module, a segment, a function, or a portion of an operation or step. For example, one or more of the blocks can be implemented as program code, hardware, or a combination of the program code and hardware. When implemented in hardware, the hardware can, for example, take the form of integrated circuits that are manufactured or configured to perform one or more operations in the flowcharts or block diagrams. When implemented as a combination of program code and hardware, the implementation may take the form of firmware. Each block in the flowcharts or the block diagrams can be implemented using special purpose hardware systems that perform the different operations or combinations of special purpose hardware and program code run by the special purpose hardware.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

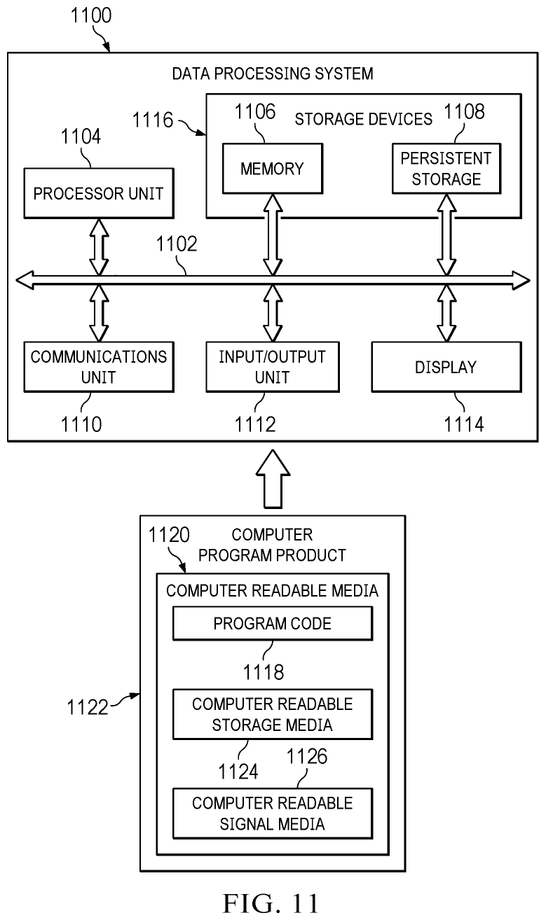

Turning now to FIG. 11, an illustration of a block diagram of a data processing system is depicted in accordance with an illustrative embodiment. Data processing system 1100 may be used to implement server computers 104 and 106 and client devices 110 in FIG. 1, as well as computer system 290 in FIG. 2. In this illustrative example, data processing system 1100 includes communications framework 1102, which provides communications between processor unit 1104, memory 1106, persistent storage 1108, communications unit 1110, input/output (I/O) unit 1112, and display 1114. In this example, communications framework 1102 takes the form of a bus system.

Processor unit 1104 serves to execute instructions for software that may be loaded into memory 1106. Processor unit 1104 may be a number of processors, a multi-processor core, or some other type of processor, depending on the particular implementation. In an embodiment, processor unit 1104 comprises one or more conventional general-purpose central processing units (CPUs). In an alternate embodiment, processor unit 1104 comprises one or more graphical processing units (GPUS).

Memory 1106 and persistent storage 1108 are examples of storage devices 1116. A storage device is any piece of hardware that is capable of storing information, such as, for example, without limitation, at least one of data, program code in functional form, or other suitable information either on a temporary basis, a permanent basis, or both on a temporary basis and a permanent basis. Storage devices 1116 may also be referred to as computer-readable storage devices in these illustrative examples. Memory 1106, in these examples, may be, for example, a random access memory or any other suitable volatile or non-volatile storage device. Persistent storage 1108 may take various forms, depending on the particular implementation.

For example, persistent storage 1108 may contain one or more components or devices. For example, persistent storage 1108 may be a hard drive, a flash memory, a rewritable optical disk, a rewritable magnetic tape, or some combination of the above. The media used by persistent storage 1108 also may be removable. For example, a removable hard drive may be used for persistent storage 1108. Communications unit 1110, in these illustrative examples, provides for communications with other data processing systems or devices. In these illustrative examples, communications unit 1110 is a network interface card.

Input/output unit 1112 allows for input and output of data with other devices that may be connected to data processing system 1100. For example, input/output unit 1112 may provide a connection for user input through at least one of a keyboard, a mouse, or some other suitable input device. Further, input/output unit 1112 may send output to a printer. Display 1114 provides a mechanism to display information to a user.

Instructions for at least one of the operating system, applications, or programs may be located in storage devices 1116, which are in communication with processor unit 1104 through communications framework 1102. The processes of the different embodiments may be performed by processor unit 1104 using computer-implemented instructions, which may be located in a memory, such as memory 1106.

These instructions are referred to as program code, computer-usable program code, or computer-readable program code that may be read and executed by a processor in processor unit 1104. The program code in the different embodiments may be embodied on different physical or computer-readable storage media, such as memory 1106 or persistent storage 1108.

Program code 1118 is located in a functional form on computer-readable media 1120 that is selectively removable and may be loaded onto or transferred to data processing system 1100 for execution by processor unit 1104. Program code 1118 and computer-readable media 1120 form computer program product 1122 in these illustrative examples. In one example, computer-readable media 1120 may be computer-readable storage media 1124 or computer-readable signal media 1126.

In these illustrative examples, computer-readable storage media 1124 is a physical or tangible storage device used to store program code 1118 rather than a medium that propagates or transmits program code 1118. Computer readable storage media 1124, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Alternatively, program code 1118 may be transferred to data processing system 1100 using computer-readable signal media 1126. Computer-readable signal media 1126 may be, for example, a propagated data signal containing program code 1118. For example, computer-readable signal media 1126 may be at least one of an electromagnetic signal, an optical signal, or any other suitable type of signal. These signals may be transmitted over at least one of communications links, such as wireless communications links, optical fiber cable, coaxial cable, a wire, or any other suitable type of communications link.

The different components illustrated for data processing system 1100 are not meant to provide architectural limitations to the manner in which different embodiments may be implemented. The different illustrative embodiments may be implemented in a data processing system including components in addition to or in place of those illustrated for data processing system 1100. Other components shown in FIG. 11 can be varied from the illustrative examples shown. The different embodiments may be implemented using any hardware device or system capable of running program code 1118.

As used herein, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

As used herein, “a number of” when used with reference to items, means one or more items. For example, “a number of different types of networks” is one or more different types of networks. In illustrative example, a “set of” as used with reference items means one or more items. For example, a set of metrics is one or more of the metrics.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

Many modifications and variations will be apparent to those of ordinary skill in the art. Further, different illustrative embodiments may provide different features as compared to other desirable embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A computer-implemented method of manufacturing analysis, the method comprising:
identifying a feature of a product model defined by geometric, physical, and systems elements with semantic labels, names or title descriptions;
creating machine readable semantic links that connect the feature to elements in an enterprise knowledge library according to a machine readable ontological knowledge model;
identifying a producibility risk or opportunity for the product model according to semantic relationships of the elements in the enterprise knowledge library linked to the feature;
alerting a user of the producibility risk or opportunity; and
adding a note to a manufacturing design specification for the product model, wherein the note provides a number of solutions for the producibility risk or opportunity, wherein the solutions are identified in the enterprise knowledge library according to the semantic relationships.

2. The method of claim 1, further comprising using a digital thread to collect and link the producibility risk or opportunity, and measured criteria relevant to the producibility risk or opportunity, to a final product for quality assurance.

3. The method of claim 1, wherein identifying the producibility risk or opportunity is performed via natural language processing.

4. The method of claim 1, wherein the feature of the product model comprises at least one of:
Package folder;
Collector;
System Block;
Behavior;
Object;
Object Property;
Object Method;
Physical product;
Part;
3D Shape specification;
Annotation set;
Note;
points;
lines;
planes;
curves;
surfaces; or
solid shapes.

5. The method of claim 1, wherein the feature of the product model comprises an entity within a computer aided design (CAD) environment that defines geometric or functional portion of a part.

6. The method of claim 1, wherein the geometric, physical, and systems elements comprise at least one of:
material properties;
ply stack thickness;
radius of curvature;
manufacturing features;
manufacturing quality;
manufacturing tools;
machining specifications;
painting specifications;
inspection specifications;
wash and dry processes;
index tool coordination features;
tool coordination;
geometric dimensioning and tolerancing; or
transportation, handling, and logistic features.

7. The method of claim 1, wherein the enterprise knowledge library comprises at least one of:
a database of manufacturing processes and process standards relevant to a feature, part, object or assembly of objects;
a database of design guidance, manuals, recommendations, checklists, processes, and practices;
a database of manufacturing assets relevant to manufacturing processes for the object;
a database of previously-identified non-conformances, defects, failure modes effect analysis, or risks relevant to manufacturing processes for the object and means of resolution or improvement of the processes; and
a database of formally modeled, machine-readable ontologies unique to a company's intellectual property, research, interests and business, and industry standards.

8. The method of claim 1, wherein identifying the producibility risk or opportunity for the product model of is performed through semantic analysis of the enterprise knowledge library.

9. The method of claim 1, wherein the solutions for the producibility risk or opportunity comprise at least one of:
a change of design specifications of the product model; or
a change of configuration of the product model.

10. The method of claim 9, wherein the design specifications comprise at least one of:
material properties;
ply stack thickness;
radius of curvature;
manufacturing features;
manufacturing quality;
manufacturing tools;
machining specifications;
painting specifications;
inspection specifications;
wash and dry processes;
index tool coordination features;
tool coordination;
geometric dimensioning and tolerancing; or
transportation, handling, and logistic features.

11. The method of claim 9, wherein configuration comprises at least one of:
material properties;
ply stack thickness;
radius of curvature;
manufacturing features;
manufacturing quality;
manufacturing tools;
machining specifications;
painting specifications;
inspection specifications;
wash and dry processes;
index tool coordination features;
tool coordination;
geometric dimensioning and tolerancing; or
transportation, handling, and logistic features.

12. The method of claim 1, wherein identifying a feature of a product model further comprises identifying a variant of the product model.

13. The method of claim 12, wherein the variant of the product model comprises a manufactured state of the product model.

14. A system for manufacturing analysis, the system comprising:
a storage device that stores program instructions;
one or more processors operably connected to the storage device and configured to execute the program instructions to cause the system to:
identify a feature of a product model defined by geometric, physical, and systems elements with semantic labels, names or title descriptions;
create machine readable semantic links that connect the feature to elements in an enterprise knowledge library according to a machine readable ontological knowledge model;
identify a producibility risk or opportunity for the product model according to semantic relationships of the elements in the enterprise knowledge library linked to the feature;
alert a user of the producibility risk or opportunity; and
add a note to a manufacturing design specification for the product model, wherein the note provides a number of solutions for the producibility risk or opportunity, wherein the solutions are identified in the enterprise knowledge library according to the semantic relationships.

15. The system of claim 14, wherein the processors further execute program instructions to cause the system to use a digital thread to collect and link the producibility risk or opportunity, and measured criteria relevant to the producibility risk or opportunity, to a final product for quality assurance.

16. The system of claim 14, wherein identifying the producibility risk or opportunity is performed via natural language processing.

17. The system of claim 14, wherein the feature of the product model comprises at least one of:
Package folder;
Collector;
System Block;
Behavior;
Object;
Object Property;
Object Method;
Physical product;
Part;
3D Shape specification;
Annotation set;
Note;
points;
lines;
planes;
curves;
surfaces; or
solid shapes.

18. The system of claim 14, wherein the feature of the product model comprises an entity within a computer aided design (CAD) environment that defines geometric or functional portion of a part.

19. The system of claim 14, wherein the geometric, physical, and systems elements comprise at least one of:
material properties;
ply stack thickness;
radius of curvature;
manufacturing features;
manufacturing quality;
manufacturing tools;
machining specifications;
painting specifications;
inspection specifications;
wash and dry processes;
index tool coordination features;
tool coordination;
geometric dimensioning and tolerancing; or
transportation, handling, and logistic features.

20. The system of claim 14, wherein the enterprise knowledge library comprises at least one of:
a database of manufacturing processes and process standards relevant to a feature, part, object or assembly of objects;
a database of design guidance, manuals, recommendations, checklists, processes, and practices;
a database of manufacturing assets relevant to manufacturing processes for the object;
a database of previously-identified non-conformances, defects, failure modes effect analysis, or risks relevant to manufacturing processes for the object and means of resolution or improvement of the processes; and
a database of formally modeled, machine-readable ontologies unique to a company's intellectual property, research, interests and business, and industry standards.

21. The system of claim 14, wherein identifying the producibility risk or opportunity for the product model of is performed through semantic analysis of the enterprise knowledge library.

22. The system of claim 14, wherein the solutions for the producibility risk or opportunity comprise at least one of:
a change of design specifications of the product model; or
a change of configuration of the product model.

23. The system of claim 22, wherein the design specifications comprise at least one of:
material properties;
ply stack thickness;
radius of curvature;
manufacturing features;
manufacturing quality;
manufacturing tools;
machining specifications;
painting specifications;
inspection specifications;
wash and dry processes;
index tool coordination features;
tool coordination;
geometric dimensioning and tolerancing; or
transportation, handling, and logistic features.

24. The system of claim 22, wherein configuration comprises at least one of:
material properties;
ply stack thickness;
radius of curvature;
manufacturing features;
manufacturing quality;
manufacturing tools;
machining specifications;
painting specifications;
inspection specifications;
wash and dry processes;
index tool coordination features;
tool coordination;
geometric dimensioning and tolerancing; or
transportation, handling, and logistic features.

25. The system of claim 14, wherein identifying a feature of a product model further comprises identifying a variant of the product model.

26. The system of claim 25, wherein the variant of the product model comprises a manufactured state of the product model.

27. A computer program product for manufacturing analysis, the computer program product comprising:
a computer-readable storage medium having program instructions embodied thereon to perform the operations of:
identifying a feature of a product model defined by geometric, physical, and systems elements with semantic labels, names or title descriptions;
creating machine readable semantic links that connect the feature to elements in an enterprise knowledge library according to a machine readable ontological knowledge model;
identifying a producibility risk or opportunity for the product model according to semantic relationships of the elements in the enterprise knowledge library linked to the feature;
alerting a user of the producibility risk or opportunity; and
adding a note to a manufacturing design specification for the product model, wherein the note provides a number of solutions for the producibility risk or opportunity, wherein the solutions are identified in the enterprise knowledge library according to the semantic relationships.
